(19) United States
(12) Patent Application Publication
(10) Pub. No.: US 2015/0046641 A1
(43) Pub. Date: Feb. 12, 2015

(54) MEMORY INTERFACE HAVING MEMORY CONTROLLER AND PHYSICAL INTERFACE

(71) Applicant: CANON KABUSHIKI KAISHA, Tokyo (JP)

(72) Inventor: Toshio Yoshihara, Kawasaki-shi (JP)

(21) Appl. No.: 14/449,345

(22) Filed: Aug. 1, 2014

(30) Foreign Application Priority Data
Aug. 6, 2013 (JP) 2013-163130

(51) Int. Cl. G11C 7/10

(52) U.S. Cl. CPC G11C 7/1072
USPC 711/105

(57) ABSTRACT

A memory interface which is capable of performing calibration of a physical interface by realizing handshake of Update Interface signals. The physical interface connects memory and a memory controller which controls the memory to each other and converts data between the memory and the memory controller. A data conversion unit is disposed between the memory controller and the physical interface, for adjusting output timing of signals output from the memory controller to the physical interface and adjusting output timing of signals output from the physical interface to the memory controller. An update process unit is disposed between the memory controller and the physical interface, for controlling executing timing of calibration for adjusting drive performance of the physical interface.

### BACKGROUND OF THE INVENTION

1. Field of the Invention

The present invention relates to a memory interface, and in particular to a memory interface using a technique for controlling signals between a memory controller and a DRAM-PHY.

2. Description of the Related Art

Generally, in information processing apparatuses, DRAM (dynamic random access memory) is often used to store an OS and data for carrying out various types of application and temporarily store data for carrying out image processing. The DRAM is used while being connected to a CPU (central processing unit), an SOC (system-on-a-chip), or the like. A module that controls access to the DRAM is usually comprised of a memory controller (MEMC) and a DRAM physical interface (PHY). The MEMC plays a role in exercising centralized control over memory interfaces such as reading and writing of data and refresh of DRAM. The PHY, which lies between the MEMC and an I/O buffer which connected to the DRAM, converts parallel data from the MEMC into serial data and sends the serial data to the DRAM by way of the I/O buffer. Further, the PHY converts serial data, which is received from the DRAM by way of the I/O buffer, into parallel data and sends the parallel data to the MEMC. Here, signals between the MEMC and the PHY are defined by DFI interface standards.

In recent years, as frequencies of memory interface signals have been increasing, various functions have been added to satisfy timing. For example, there has been proposed a technique that has a delay circuit in order to correct for the effect of temperature and voltage and performs calibration that adjusts drive performance of a memory device during normal memory operation (see Japanese Laid-Open Patent Publication (Kokai) No. 2011-108351).

DFI interface standards as well provide Update Interface which is a system for performing calibration that corrects output drive performance of the PHY in response to temperature and voltage changes. Specifically, first, the PHY detects a change in temperature or voltage by monitoring a resistance value outside a chip, and determines whether or not it is necessary to perform calibration. When the PHY determines that it is necessary to perform calibration, it asserts a request (REQ) signal, which requests execution of calibration, to the MEMC. Upon receiving the request signal, the MEMC asserts an acknowledgement (ACK) signal, which permits execution of calibration. It should be noted that an output signal from the PHY will not be stable if a command is received from the MEMC while the PHY is correcting output drive performance, and hence the MEMC is not allowed to output a command to the PHY when asserting the ACK signal.

Thus, according to DFI interface standards, handshake of signals between the MEMC and the PHY is realized so as to perform calibration that corrects output drive performance of the PHY in response to temperature and voltage changes.

However, when there is a mismatch between versions of DFI interface standards which the MEMC and the PHY are compliant with, there is fear that Update Interface cannot be performed. For example, DFI 2.1 supports Update Interface, whereas DFI 2.0 does not support Update Interface. Namely, when the MEMC compliant with DFI 2.1 and the PHY compliant with DFI 2.0 are connected together, the MEMC cannot realize handshake of Update Interface signals even if it is necessary for the PHY to perform calibration. Thus, the PHY cannot perform calibration, and hence signal qualities such as timing cannot be ensured.

Moreover, it is necessary to inhibit output of commands by the MEMC during execution of the PHY calibration, and hence memory access performance may deteriorate due to execution of the PHY calibration on a regular basis.

### SUMMARY OF THE INVENTION

The present invention provides a memory interface which is capable of performing calibration of a physical interface (PHY) by realizing handshake of Update Interface signals.

Accordingly, an aspect of the present invention provides a memory interface comprising a memory controller configured to control memory, a physical interface configured to connect the memory and the memory controller to each other and convert data between the memory and the memory controller, a data conversion unit configured to be disposed between the memory controller and the physical interface, for adjusting output timing of signals output from the memory controller to the physical interface and adjusting output timing of signals output from the physical interface to the memory controller, and an update process unit configured to be disposed between the memory controller and the physical interface, for controlling executing timing of calibration for adjusting drive performance of the physical interface.

According to the present invention, even when there is a mismatch between versions of DFI interface standards which the memory controller and the physical interface are compliant with, and the memory controller or the physical interface does not support Update Interface, the update conversion block which is a substitute for Update Interface is provided between the memory controller and the physical interface, and in synchronization with a command issued by the memory controller, the update conversion block controls execution timing of calibration for adjusting drive performance of the physical interface, whereby handshake of Update Interface signals can be realized to perform calibration of the physical interface.

Further features of the present invention will become apparent from the following description of exemplary embodiments (with reference to the attached drawings).

### BRIEF DESCRIPTION OF THE DRAWINGS

FIG. 1 is a block diagram schematically showing an overall arrangement of an image processing apparatus having a memory interface according to a first embodiment of the present invention.

FIG. 2 is a block diagram schematically showing an arrangement of a memory block in FIG. 1.

FIG. 3 is a timing chart which is useful in explaining basic operation of an update process block in FIG. 2.

FIG. 4 is a flowchart showing basic operation of the update process block in FIG. 3.

FIG. 5A is a timing chart which is useful in explaining operation of the update process block during power-on initialization. FIG. 5B is a timing chart which is useful in explaining operation of the update process block during normal operation. FIG. 5C is a timing chart which is useful in explaining operation of the update process block during self-refresh of DRAM.

FIG. 6 is a block diagram schematically showing an arrangement of a data conversion block in FIG. 2.

FIG. 7A is a timing chart of signals related to a read command enable signal from a DFI-CH0 in a case where the number of cycles in read latency is an even number. FIG. 7B is a timing chart of signals related to a read command enable signal from a DFI-CH1 in a case where the number of cycles in read latency is an even number.

FIG. 8A is a timing chart of signals related to a read command enable signal from the DFI-CH0 in a case where the number of cycles in read latency is an odd number. FIG. 8B is a timing chart of signals related to a read command enable signal from the DFI-CH1 in a case where the number of cycles in read latency is an odd number.

FIG. 9 is a timing chart of read data signals in a case where read data valid signals are in phase on the DFI-CH0 and the DFI-CH1.

FIG. 10 is a timing chart of read data signals in a case where read data valid signals are in different phases on the DFI-CH0 and the DFI-CH1.

FIG. 11 is a timing chart of signals related to a write data enable signal from the DFI-CH0 in a case where the number of cycles in write latency is an even number.

FIG. 12 is a timing chart of signals related to a write data enable signal from the DFI-CH1 in a case where the number of cycles in write latency is an even number.

FIG. 13 is a timing chart of signals related to a write data enable signal from the DFI-CH0 in a case where the number of cycles in write latency is an odd number.

FIG. 14 is a timing chart of signals related to a write data enable signal from the DFI-CH1 in a case where the number of cycles in write latency is an odd number.

FIG. 15 is a timing chart which is useful in explaining operation of the update process block during self-refresh of the DRAM according to a second embodiment of the present invention.

### DESCRIPTION OF THE EMBODIMENTS

The present invention will now be described in detail with reference to the drawings showing embodiments thereof.

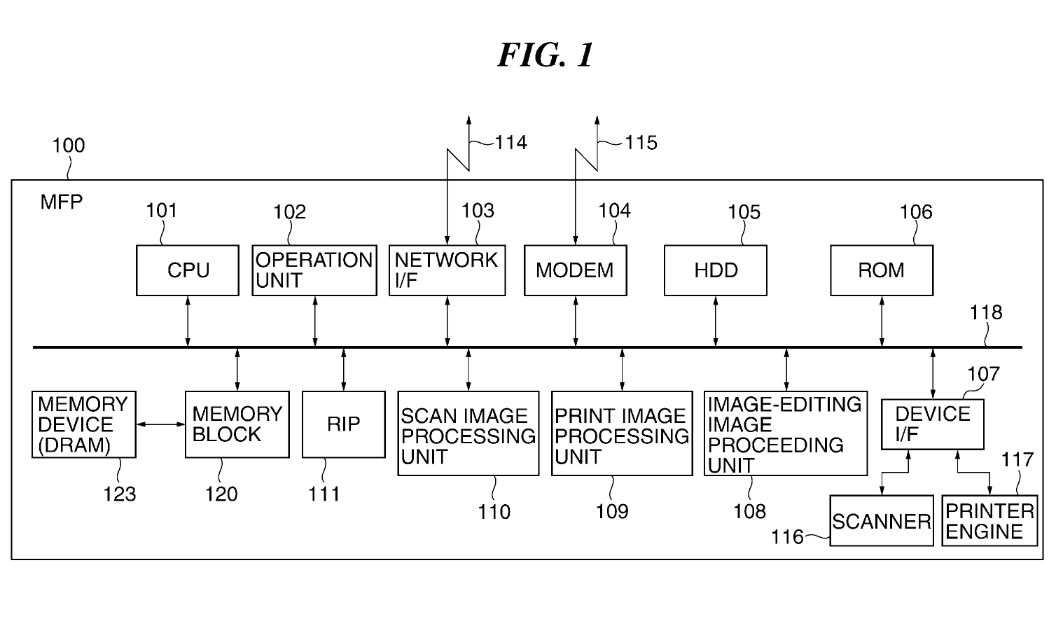

FIG. 1 is a block diagram schematically showing an overall arrangement of an image processing apparatus having a memory interface according to a first embodiment of the present invention.

Referring to FIG. 1, an MFP 100 has a scanner 116, which is an image input device, and a printer engine 117, which is an image output device. The scanner 116 and the printer engine 117 read image data and produce printouts.

The CPU 101 is a central processing device for controlling the MFP 100. An operation unit 102 receives operating instructions from a user and displays operation results. A network I/F 103, which is implemented by, for example, a LAN card, is connected to a LAN 114 and inputs and outputs device information and image data from and to an external apparatus (not shown). A modem 104, which is connected to a public line 115, inputs and outputs control information from and to an external apparatus (not shown). An HDD 105, which is a hard disk drive, stores system software for various types of processing, input image data, and so on. A ROM 106, which is a boot ROM, stores a system boot program.

A device I/F 107, which is connected to the scanner 116 and the printer engine 117, carries out an image transfer process. An image editing image processing unit 108 carries out various types of image processing such as rotation and zooming of image data, color processing, trimming and masking, binary coding, multilevel coding, and blank sheet judgment. A print image processing unit 109 carries out an image correction process, which is appropriate to the printer engine 117, for image data to be printed out.

A scan image processing unit 110 carries out various processes such as correction, processing, and editing on image data read by the scanner 116. A RIP (raster image processor) 111 decompresses page description language (PDL) codes into image data.

A memory block 120 converts memory access commands from, for example, the CPU 101 and various image processing units described above into command interpretable by a memory device (DRAM) 123 and accesses the DRAM 123. The DRAM 123, which is a system work memory for operation of the CPU 101, is an image memory for temporarily storing input image data. The units described above are placed on a system bus 118.

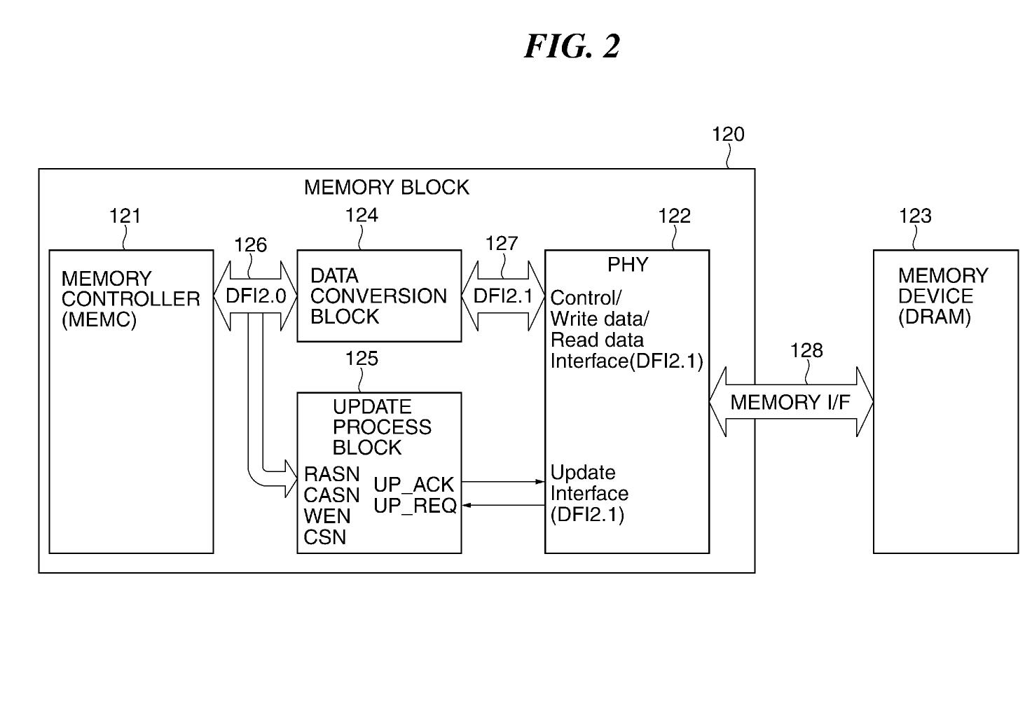

FIG. 2 is a block diagram schematically showing an arrangement of the memory block 120 in FIG. 1.

Referring to FIG. 2, the memory block 120 is comprised of a memory controller (MEMC) 121, a physical interface (PHY) 122, a data conversion block 124, and an update process block 125.

The MEMC 121 plays a role in exercising centralized control over memory interfaces such as reading and writing of data and refresh of the DRAM 123. A module for accessing memory is connected to the MEMC 121 via a bus or the like although this is not shown in the figure. To access the DRAM 123, the module issues a command based on a bus protocol, and the MEMC 121 receives the command. The MEMC 121 converts the received command into a DFI which is an interface to the PHY 122. It should be noted that the DFI has channels 0 and 1 which input and output signals, and in the following description, they will be referred to as the DFI-CH0 and the DFI-CH1.

The PHY 122, which lies between the MEMC 121 and an I/O buffer, not shown, which is connected to the DRAM 123, converts parallel data from the MEMC 121 into serial data and sends the serial data to the DRAM 123 by way of the I/O buffer. The DRAM 123 receives a command based on a memory protocol via a memory I/F 128 and stores and reads data.

The data conversion block 124 is disposed between the MEMC 121 and the PHY 122. The data conversion block 124 is connected to the MEMC 121 via an I/F 126 based on DFI 2.0 and connected to the PHY 122 via an I/F 127 based on DFI 2.1.

The data conversion block 124 is a module that adjusts signal output timing so as to correct for a mismatch in signal output timing due to a difference in version between DFI 2.0 and DFI 2.1. A detailed description will be given later of how signal output timing is adjusted.

The update process block 125 analyzes a command output from the MEMC 121 and asserts an UP_ACK signal which permits execution of PHY calibration when an UP_REQ signal, which is an Update Interface signal and requests execution of PHY calibration, is asserted. Specifically, the update process block 125 analyzes a RASN, CASN, WEN, or CSN signal from the MEMC 121 and determines whether or not a ZQCS (ZQ calibration short) command or a ZQCL (ZQ calibration long) command has been issued. When it is determined that the ZQCS command or the ZQCL command has been issued by the MEMC 121, and the UP_REQ signal has been asserted, the update process block 125 asserts the UP_ACK signal.

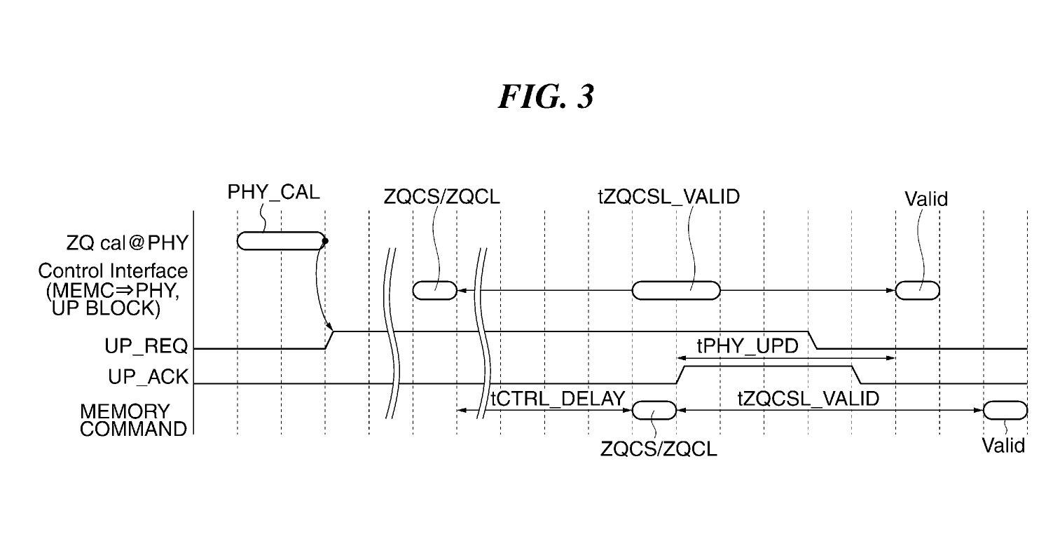

FIG. 3 is a timing chart which is useful in explaining basic operation of the update process block 125 in FIG. 2.

Referring to FIG. 3, ZQ cal@PHY indicates execution timing of calibration as a process to update the PHY 122. Namely, when a change in temperature or voltage conditions is detected, and it is necessary to change drive performance of a signal which is output to the DRAM 123, the PHY 122 issues a PHY_CAL command. When the PHY_CAL command is issued, the PHY 122 asserts an UP_REQ signal to the update process block 125. In response to issuance of an UP_CAL command by the PHY 122, the MEMC 121 issues the ZQCS command or the ZQCL command to the update process block 125. The ZQCS command and the ZQCL command are commands for performing automatic calibration of a terminal resistor value (ODT value) in the DRAM 123 when they are received by the DRAM 123. The ZQCL command is issued at the time of initialization, and the ZQCS command is issued during operation.

The update process block 125 determines whether or not a command issued by the MEMC 121 is the ZQCS/ZQCL command, and issues the ZQCS/ZQCL command as a memory command to the DRAM 123 a tCTRL_DELAY time period after the issuance of the ZQCS/ZQCL command via the PHY 122.

The update process block 125 also asserts the UP_ACK signal the tCTRL_DELAY time period after the issuance of the ZQCS/ZQCL command. Thus, after the ZQCS/ZQCL command is issued, the PHY 122 performs PHY calibration that adjusts drive performance of the PHY 122.

In response to the assertion of the UP_ACK signal, the PHY 122 performs PHY calibration. The MEMC 121 issues a valid command a tZQCSL_VALID time period after the issuance of the ZQCS/ZQCL command. Normal termination of the PHY calibration is acknowledged by the issuance of this valid command. The tZQCSL_VALID time period is a time period determined based on memory standards.

A tPHY_UPD time period is a time period over which the PHY 122 performs PHY calibration, and the PHY calibration is required to be terminated before the valid command is issued by the MEMC 121. Namely, when the ZQCS command or the ZQCL command is issued by the MEMC 1121, and the UP_REQ signal is asserted, first, the update process block 125 issues a memory command to the DRAM 123. The update process block 125 then asserts the UP_ACK signal, and the PHY 122 performs PHY calibration, and before the valid command is issued by the MEMC 121, terminates the PHY calibration. Thus, when the ZQCS/ZQCL command is issued by the MEMC 121, calibration of the PHY 122 can be performed.

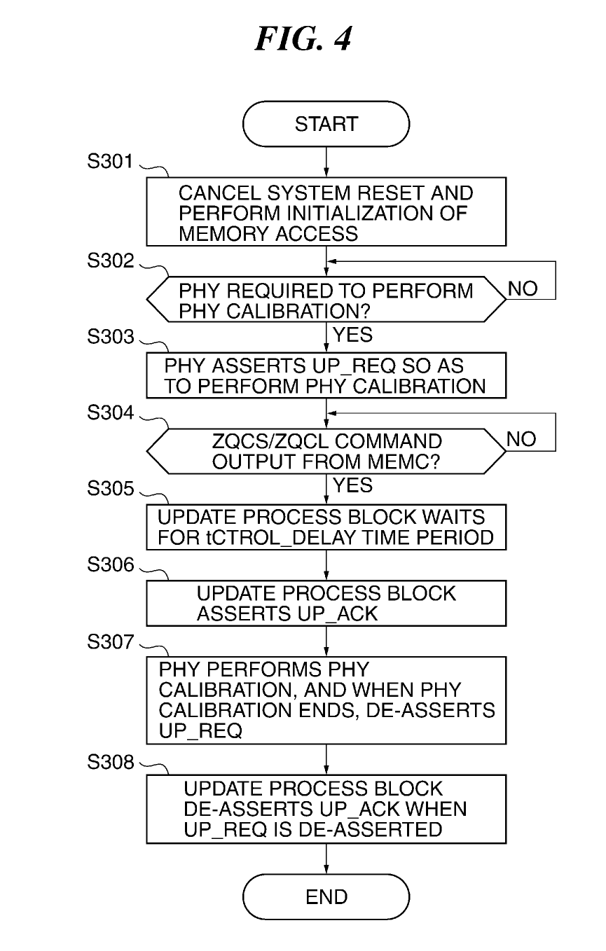

FIG. 4 is a flowchart showing basic operation of the update process block 125 in FIG. 3.

First, in step S301, system reset of a register held in the MEMC 121 is canceled, and the CPU 101 carries out initialization for accessing memory, followed by the process proceeding to step S302.

In step S302, the PHY 122 determines whether or not it is necessary to perform PHY calibration. When the PHY 122 determines that it is necessary to perform PHY calibration, the process proceeds to step S303.

In the step S303, the PHY 122 issues a PHY_CAL command so as to perform PHY calibration and asserts an UP_REQ signal, followed by the process proceeding to step S304.

In the step S304, the update process block 125 determines whether or not the ZQCS/ZQCL command has been issued by the MEMC 121. When the update process block 125 determines that the ZQCS/ZQCL command has been issued by the MEMC 121, the process proceeds to step S305.

In the step S305, the update process block 125 stands by for a tCTRL_DELAY time period, followed by the process proceeding to step S306.

In the step S306, the update process block 125 asserts an UP_ACK signal which permits execution of PHY calibration, followed by the process proceeding to step S307.

In the step S307, the PHY 122 performs PHY calibration, and when the PHY calibration is brought to an end, the PHY 122 de-asserts the UP_REQ signal, followed by the process proceeding to step S308.

In the step S308, in response to the de-assertion of the UP_REQ signal, the update process block 125 de-asserts the UP_ACK signal and terminates the present process.

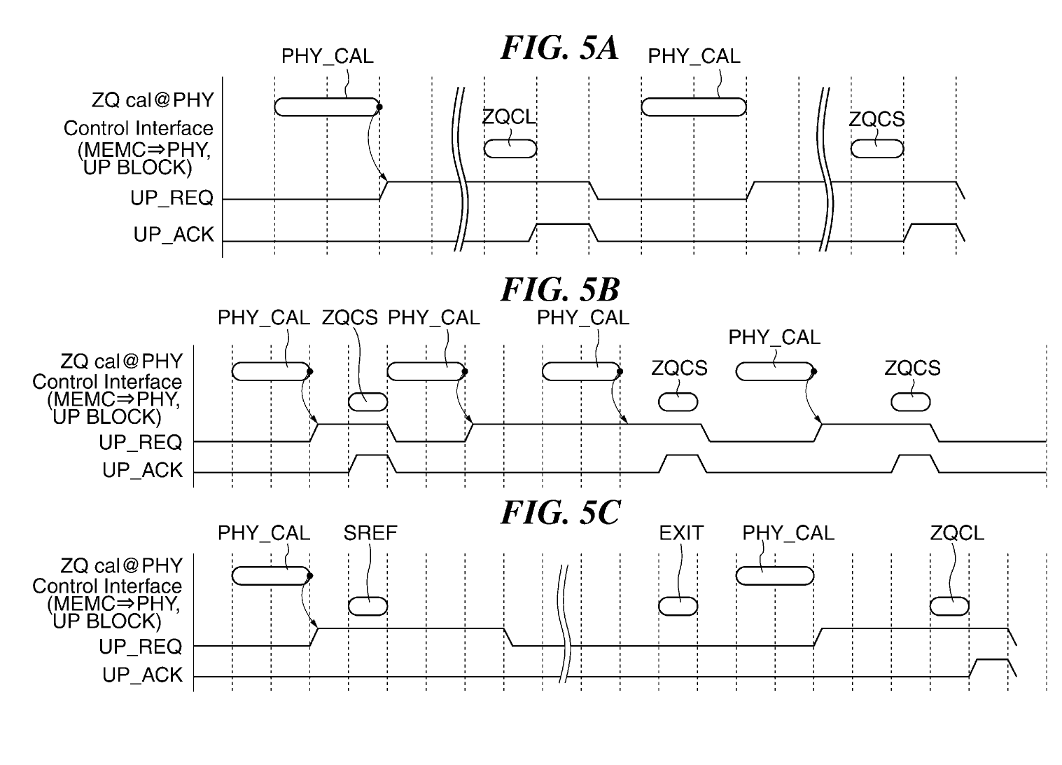

FIG. 5A is a timing chart which is useful in explaining operation of the update process block 125 during power-on initialization.

First, when to first PHY_CAL command is issued by the PHY 122, and an UP_REQ signal is asserted, the MEMC 121 issues a ZQCL command, which is a command for initialization. As a result, the update process block 125 asserts an UP_ACK signal, and calibration of the PHY 122 is performed. After that, a second PHY_CAL command is issued, and the UP_ACK signal is asserted by the ZQCS command, second PHY calibration is performed.

FIG. 5B is a timing chart which is useful in explaining operation of the update process block 125 during normal operation.

FIG. 5B shows a case where a time period over which calibration of the PHY 122 is performed is shorter than an interval at which the ZQCS command is issued. When a first PHY_CAL command is issued, an UP_REQ signal for first PHY calibration is asserted. Thereafter, when an UP_ACK signal is asserted by the ZQCS command, PHY calibration is performed. When a second PHY_CAL command is then issued, the UP_REQ signal de-asserted at the end of the first PHY calibration is asserted again, but at this time, PHY calibration is not performed because the ZQCS command is not issued, and the UP_ACK signal is not asserted. Thereafter, when a third PHY_CAL command is issued, the ZQCS command has been kept asserted since the ZQCS command was issued last time. After that, when the ZQCS command is issued, and the UP_ACK signal is asserted, PHY calibration is performed again.

FIG. 5C is a timing chart which is useful in explaining operation of the update process block 125 during self-refresh of the DRAM 123.

During self-refresh of the DRAM 123, it is unnecessary for the PHY 122 to perform PHY calibration, and hence neither an UP_ACK signal nor an UP_ACK signal is asserted. FIG. 5C shows a case where an UP_REQ signal is asserted by a PHY_CAL command, and then an SREF command, which is a self-refresh command for the DRAM 123, is issued by the MEMC 121.

In a sequence of shifting into self-refresh of the DRAM 123, the CPU 101 accesses the PHY 122 and resets execution of PHY calibration. As a result, the asserted UP-REQ signal is de-asserted. After that, in a sequence of returning from self-refresh of the DRAM 123, the CPU 101 accesses the PHY 122 and cancels the reset of execution of PHY calibration. Then, an EXIT command, which is a command to return from self-refresh of the DRAM 123, is issued by the MEMC 121. The subsequent operation is the same as that in the case of normal operation shown in FIG. 5B.

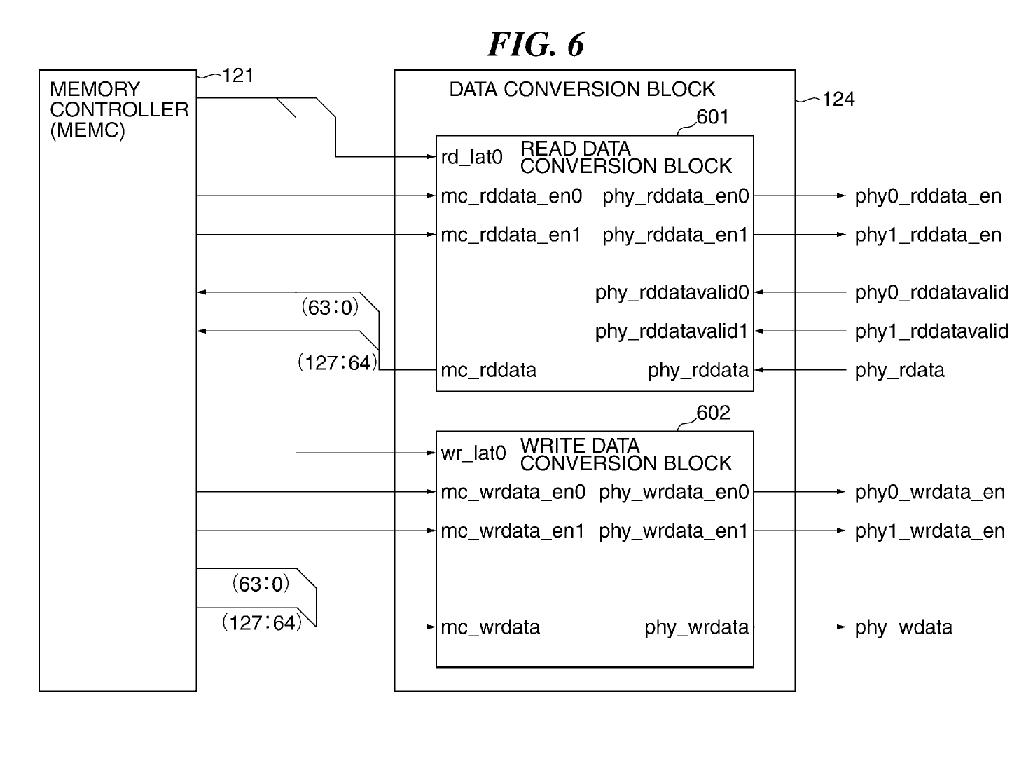

FIG. 6 is a block diagram schematically showing an arrangement of the data conversion block 124 in FIG. 2.

As described above, because the MEMC 121 and the PHY 122 compliant with different versions of DFI (2.1 and 2.0) output signals (data signals and enable signals) in different timing, signals cannot be directly input and output to and from each other. To cope with this, in the present embodiment, the data conversion block 124 is provided to adjust output timing of data signals and enable signals so as to correct for a mismatch between versions DFI 2.0 and DFI 2.1. The data conversion block 124 has a read data conversion block 601 and a write data conversion block 602.

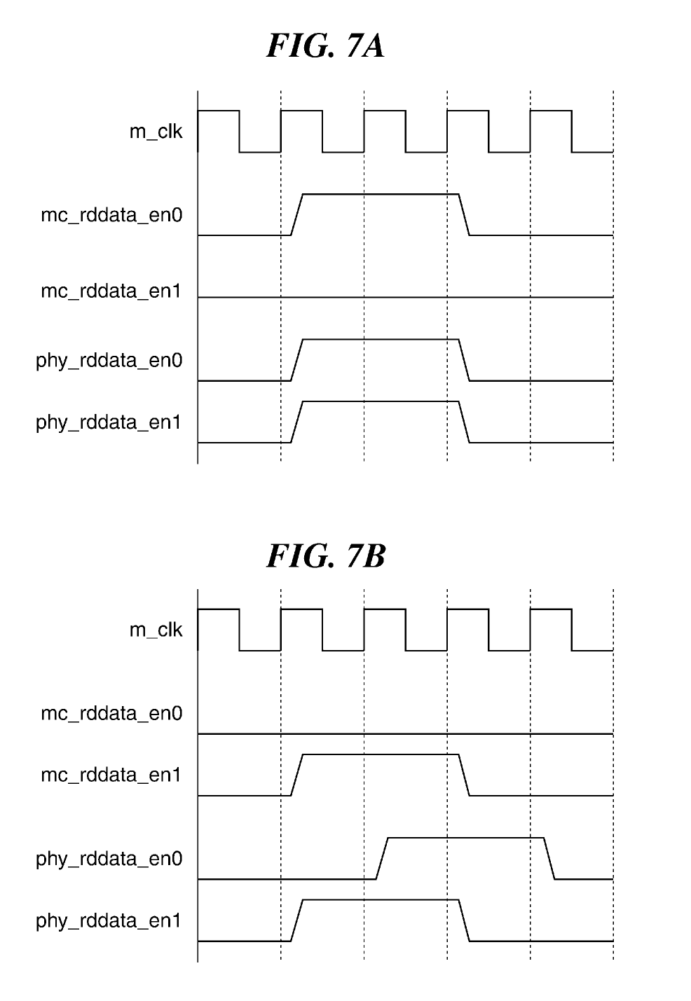

The read data conversion block 601 is a block that adjusts output timing of read data (rddata) signals and read command enable (rddata_en) signals between the MEMC 121 and the PHY 122 so as to correct for a mismatch between DFI versions. In the figure, rd_lat0 is a signal indicative of whether the number of cycles in read latency which is a delay time between issuance of a read request to memory and return of a response to the read request is an odd number or an even number, and depending on whether the number of cycles is an odd number or an even number, operation of the read data conversion block 601 is changed (see FIGS. 7A to 10 referred to later). Here, read latency is Cas latency+Additive latency when memory is, for example, DDR3.

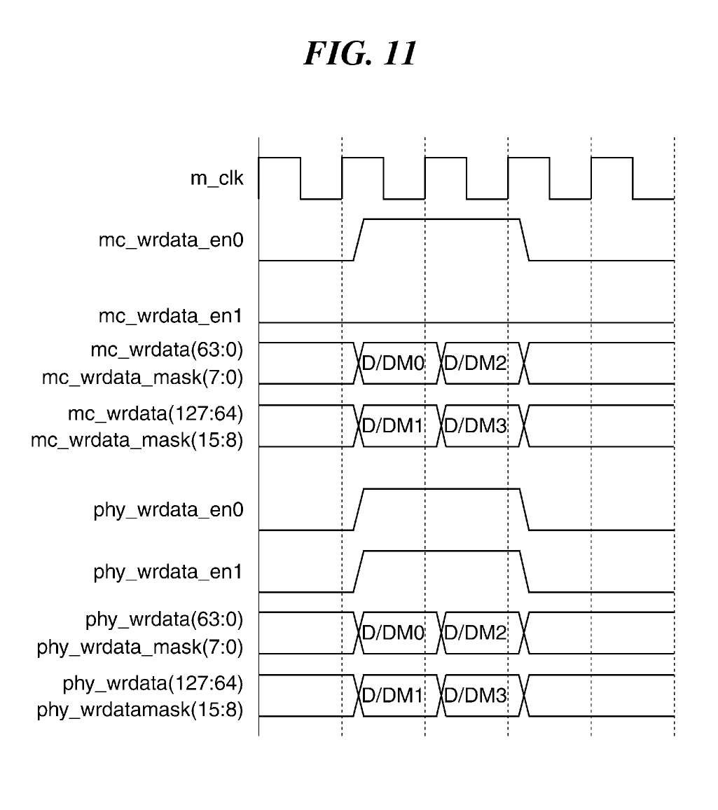

The write data conversion block 602 is a block that adjusts output timing of write data (wrdata) signals and write data enable (wrdata_en) signals between the MEMC 121 and the PHY 122 so as to correct for a mismatch between DFI versions. In the figure, wr_lat0 is a signal indicative of whether the number of cycles in write latency which is a delay time between issuance of a write request to memory and return of a response to the write request is an odd number or an even number, and depending on whether the number of cycles is an odd number or an even number, operation of the write data conversion block 601 is changed (see FIGS. 11 to 14 referred to later). Here, write latency is Cas write latency+Additive latency when memory is, for example, DDR3.

Referring to FIGS. 7A to 14, a description will be given of operation of the read data conversion block 601 during reading of read data and operation of the write data conversion block 602 during during writing of write data. It should be noted that as for signal names below, “mc_” is added to names of signals between the MEMC 121 and the data conversion block 124, and “phy_” is added to names of signals between the data conversion block 124 and the PHY 122. Also, “_en0” is added to names of signals passing through the DFI-CH0, and “_en1” is added to names of signals passing through the DFI-CH1. Further, in timing charts below, signals are synchronized with m_clk which is a main clock signal for signal synchronization.

Referring first to FIGS. 7A to 10, a description will be given of operation of the read data conversion block 601 during reading of read data. Reading of read data from the DRAM 123 is started by the MEMC 121 outputting a read command enable signal.

FIG. 7A is a timing chart of command enable signals in a case where a read command enable signal from the DFI-CH0 is input to the read data conversion block 601 when the number of cycles in read latency described above is an even number.

When an mc_rddata_en0 signal output from the MEMC 121 is input to the read data conversion block 601, the read data conversion block 601 outputs a phy_rddata_en0 signal and a phy_rddata_en1 signal as data with the same timing and the same width as the mc_rddata_en0 signal to the PHY 122. Namely, the phy_rddata_en0 signal and the phy_rddata_en1 signal that are output are in phase.

FIG. 7B is a timing chart of read command enable signals in a case where a read command enable signal from the DFI-CH1 is input to the read data conversion block 601 when the number of cycles in read latency is an even number.

When an mc_rddata_en1 signal output from the MEMC 121 is input to the read data conversion block 601, the read data conversion block 601 outputs, to the PHY 122, a phy_rddata_en1 signal as data with the same timing and the same width as the mc_rddata_en1 signal. The read data conversion block 601 also outputs, to the PHY 122, a phy_rddata_en1 signal as data with the same width as the mc_rddata_en1 signal and with timing that is one cycle of m_clk later. Namely, the phy_rddata_en0 signal and the phy_rddata_en1 signal that are output are in different phases.

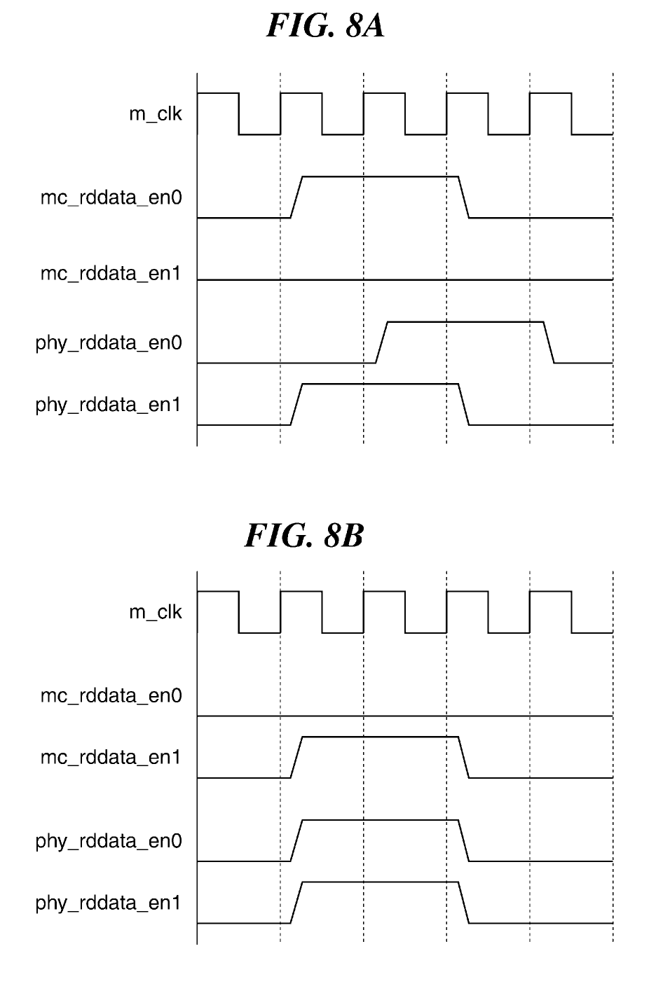

FIG. 8A is a timing chart of read command enable signals in a case where a read command enable signal from the DFI-CH0 is input to the read data conversion block 601 when the number of cycles in read latency is an odd number.

When an mc_rddata_en0 signal output from the MEMC 121 is input to the read data conversion block 601, the read data conversion block 601 outputs, to the PHY 122, a phy_rddata_en1 as data with the same timing and the same width as the mc_rddata_en0 signal. The read data conversion block 601 also outputs, to the PHY 122, a phy_rddata_en0 signal as data with the same width as the mc_rddata_en0 signal and with timing that is one cycle of m_clk later. Namely, the phy_rddata_en0 signal and the phy_rddata_en1 signal that are output are in different phases.

FIG. 8B is a timing chart of read command enable signals in a case where a read command enable signal from the DFI-CH1 is input to the read data conversion block 601 when the number of cycles in read latency is an odd number.

When an mc_rddata_en1 signal output from the MEMC 121 is input to the read data conversion block 601, the read data conversion block 601 outputs, to the PHY 122, a phy_rddata_en0 signal and a phy_rddata_en1 signal as data with the same timing and the same width as the mc_rddata_en1 signal. Namely, the phy_rddata_en0 signal and the phy_rddata_en1 signal that are output are in phase.

Thus, in each of the cases shown in FIGS. 7A and 8B, the read data conversion block 601 adjusts output timing of read command enables signals. Upon receiving read command enable signals from the read data conversion block 601, the PHY 122 reads read data from the DRAM 123 and outputs read data valid (rddatavalid) signals and read data signals to the read data conversion block 601.

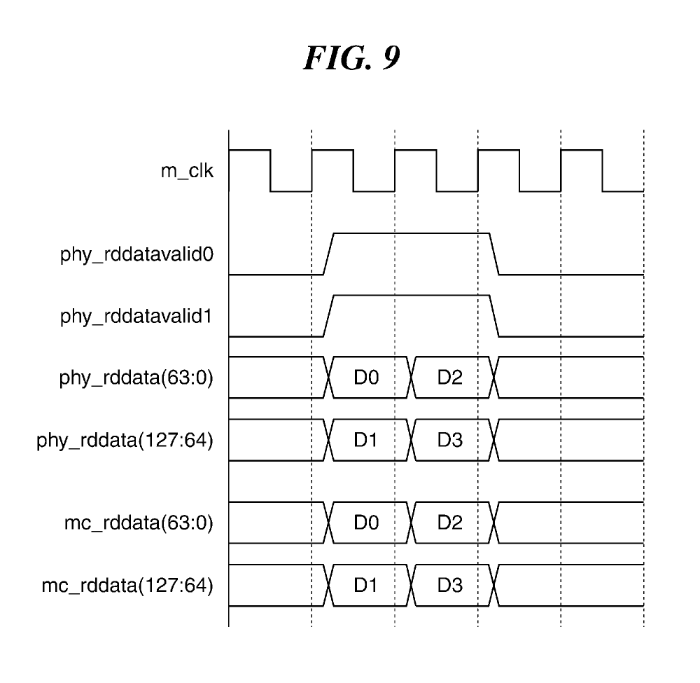

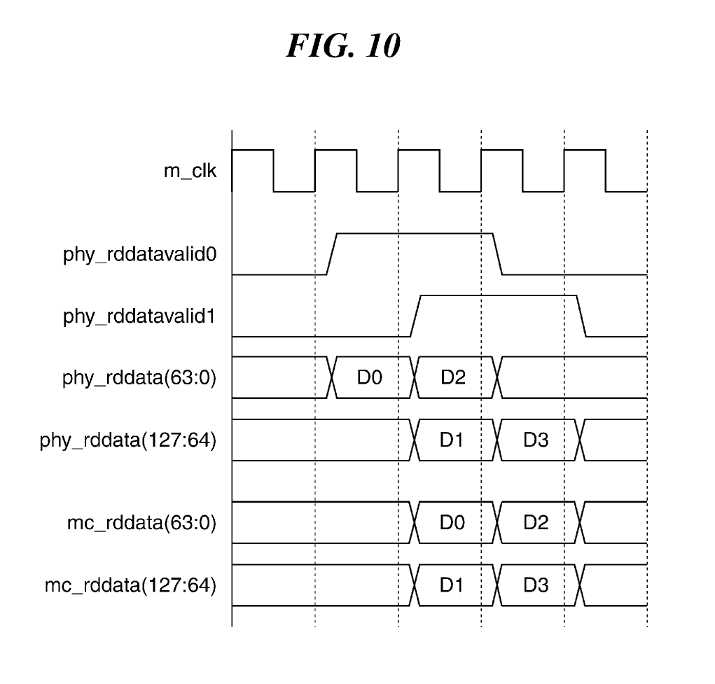

Referring now to FIGS. 9 and 10, a description will be given of how output timing of read data signals read from the DRAM 123 by the PHY 122 is adjusted.

FIG. 9 is a timing chart of read data signals in a case where read data valid signals output from the PHY 122 are in phase on the DFI-CH0 and the DFI-CH1 in relation to adjustment of output timing with which read data is output from the PHY 122 to the MEMC 121. It should be noted that the case where read data valid signals are in phase corresponds to a case where the phy_rddata_en0 signal and the phy_rddata_en1 signal are output in phase in FIGS. 7A and 8B. Read data signals are comprised of a lower bit signal ([63:0]) and an upper bit signal ([127:64]).

Referring to FIG. 9, when a phy_rddata [63:0] signal and a phy_rddata [127:64] signal output from the PHY 122 as well as a phy_rddatavalid0 signal and a phy_rddatavalid1 signal are input to the read data conversion block 601, the read data conversion block 601 outputs an mc_rddata [63:0] signal and an mc_rddata [127:64] signal with the same timing as the phy_rddata [63:0] signal and the phy_rddata [127:64] signal to the MEMC 121.

FIG. 10 is a timing chart of read data signals in a case where read data valid signals output from the PHY 122 are in different phases on the DFI-CH0 and the DFI-CH1 in relation to adjustment of output timing with which read data is output from the PHY 122 to the MEMC 121. It should be noted that the case where read data valid signals are in different phases corresponds to a case where the phy_rddata_en0 signal and the phy_rddata_en1 signal are output in different phases in FIGS. 7B and 8A.

Referring to FIG. 10, when a phy_rddatavalid0 signal and a phy_rddata [63:0] signal output from the PHY 122 are input to the read data conversion block 601, and thereafter, a phy_rddatavalid1 signal and a phy_rddata [127:64] signal are input to the read data conversion block 601, the read data conversion block 601 outputs an mc_rddata [63:0] signal and an mc_rddata [127:64] signal with the same timing as the phy_rddatavalid1 signal to the MEMC 121. Namely, a signal which is one cycle of m_clk later than the phy_rddata [63:0] signal is output as the mc_rddata [63:0] signal.

Thus, as for read data, the read data conversion block 601 determines output timing of read data signals output from the PHY 122 to the MEMC 121 based on a phase difference between read data valid signals when the DFI-I/F channel is CH0 and when the DFI-I/F channel is CH1.

Referring next to FIGS. 11 to 14, a description will be given of operation of the write data conversion block 602 during writing of write data. Writing of write data into the DRAM 123 is started by the MEMC 121 outputting a write data enable signal. Here, write data signals are comprised of a lower bit signal ([63:0]) and an upper bit signal ([127:64]). Mask signals are signals, which are signals that control output by masking a specific bit, are comprised of a lower bit signal ([7:0]) and an upper bit signal ([15:8]).

FIG. 11 is a timing chart of signals in a case where the number of cycles in write latency is an even number, and a write data enable signal from the DFI-CH0 is input to the write data conversion block 602 in relation to adjustment of output timing of write data from the MEMC 121 to the PHY 122.

Referring to FIG. 11, when an mc_wrdata_en0 signal is input from the MEMC 121 to the write data conversion block 602, the write data conversion block 602 outputs a phy_wrdata_en0 signal and a phy_wrdata_en1 signal with the same timing as the mc_wrdata_en0 signal to the PHY 122. Likewise, when an mc_wrdata signal and an mc_wrdata mask signal are input from the MEMC 121 to the write data conversion block 602, the write data conversion block 602 outputs a phy_wrdata signal and a phy_wrdata mask signal with the same timing as the phy_wrdata_en0 signal and the phy_wrdata_en1 signal to the PHY 122.

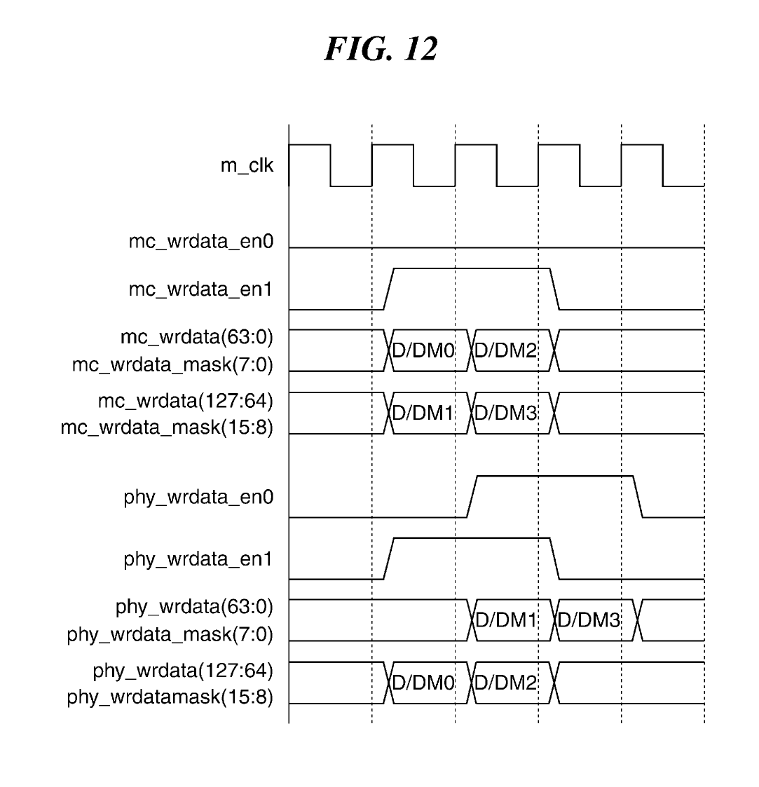

FIG. 12 is a timing chart of signals in a case where a write data enable signal from the DFI-CH1 is input to the write data conversion block 602 when the number of cycles in write latency is an even number in relation to adjustment of output timing with which write data is output from the MEMC 121 to the PHY 122.

First, as for write data enable signals, when an mc_wrdata_en1 signal is input from the MEMC 121 to the write data conversion block 602, the write data conversion block 602 outputs a phy_wrdata_en1 signal with the same timing as the mc_wrdata_en1 signal to the PHY 122. The write data conversion block 602 then outputs a phy_wrdata_en0 signal with timing which is one cycle of m_clk later than the mc_wrdata_en1 signal to the PHY 122.

Next, as for write data enable signals, when an mc_wrdata [63:0] signal and an mc_wrdata mask [7:0] signal are output from the MEMC 121 to the write data conversion block 602, the write data conversion block 602 outputs a phy_wrdata [127:64] signal and a phy_wrdata mask [15:8] signal with the same timing as the phy_wrdata_en1 signal to the PHY 122. Also, when an mc_wrdata [127:64] signal and an mc_wrdata mask [15:8] signal are input from the MEMC 121 to the write data conversion block 602, the write data conversion block 602 outputs a phy_wrdata [63:0] signal and an mc_wrdata mask [7:0] signal to the PHY 122 with the same timing as the phy_wrdata_en0 signal one cycle of m_clk later than the mc_wrdata_en1 signal.

Referring to FIG. 12, when write data signals and mask signals are input to and output from the write data conversion block 602, output timing of a lower bit (0 to 63) signal and output timing of an upper bit (127 to 64) signal are opposite, and they are output with the same timing as phy_wridata_en signals which they correspond to.

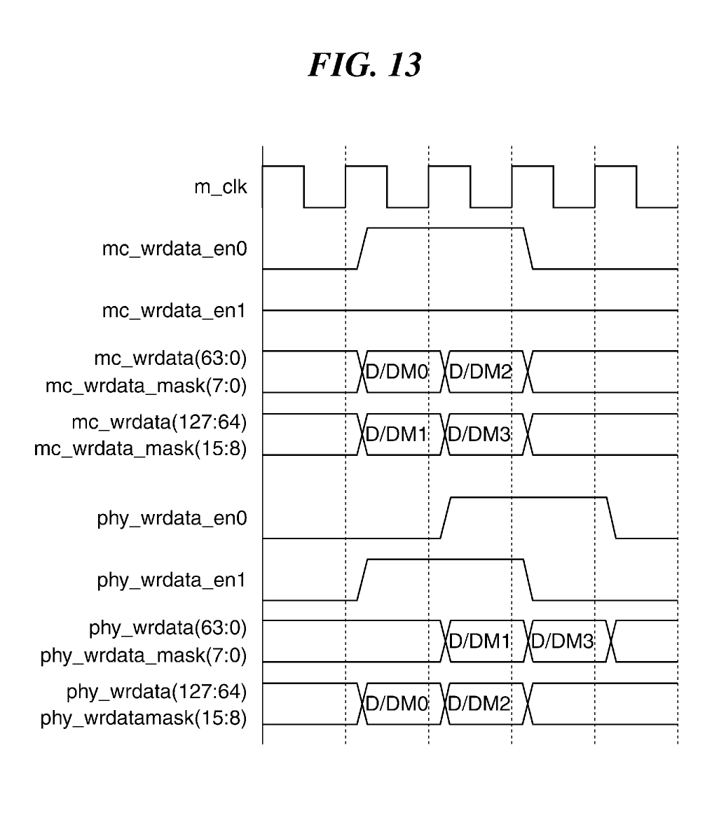

FIG. 13 is a timing chart of signals in a case where a write data enable signal from the DFI-CH0 is input to the write data conversion block 602 when the number of cycles in write latency is an odd number in relation to adjustment of output timing with which write data is output from the MEMC 121 to the PHY 122.

Description of the conversion method in FIG. 13 is omitted here because the mc_wrdata_en0 signal just replaces the mc_wrdata_en1 signal described with reference to FIG. 12.

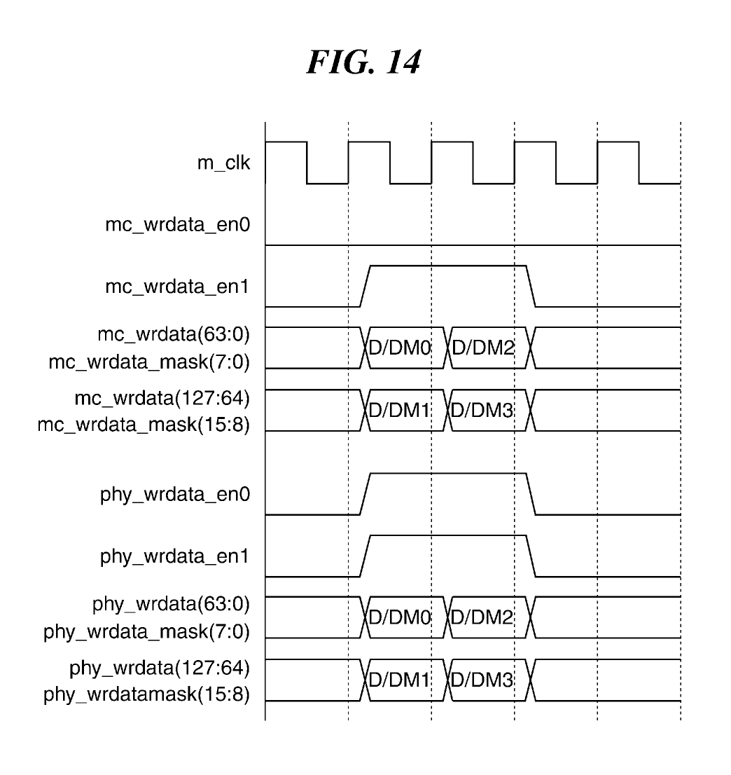

FIG. 14 is a timing chart of signals in a case where a write data enable signal from the DFI-CH1 is input to the write data conversion block 602 when the number of cycles in write latency is an odd number in relation to adjustment of output timing with which write data is output from the MEMC 121 to the PHY 122.

Description of the conversion method in FIG. 14 is omitted here because the mc_wrdata_en1 signal just replaces the mc_wrdata_en0 signal described with reference to FIG. 11.

As described above, because there is the update process block 125, handshake of Update Interface signals between the MEMC 121 and the PHY 122 can be realized, and PHY calibration can be appropriately performed. Moreover, because PHY calibration is performed in synchronization with the timing with which the ZQCS/ZQCL command is issued by the MEMC 121, degradation of memory access performance can be prevented. Further, as for a mismatch in the timing of signals arising from a mismatch between the versions of DFI interface standards as well, because there is the data conversion block 124, output timing of data signals and enable signals between the MEMC 121 and the PHY 122 is adjusted, so that they can be output with timing suitable for the MEMC 121 and the PHY 122. Namely, because there are the update process block 125 and the data conversion block 124, a mismatch between the versions of DFI interface standards which the MEMC 121 and the PHY 122 are compliant with can be eliminated.

In the first embodiment described above, PHY calibration is not performed during self-refresh of the DRAM 123 as shown in FIG. 5C.

On the other hand, in a method according to a second embodiment described hereafter, when a request to perform PHY calibration is issued during self-refresh of the DRAM 123, PHY calibration is immediately performed. It should be noted that the same components as those of the first embodiment are designated by the same reference symbols, detailed description of which, therefore, is omitted. Only those differing from the first embodiment will be described below.

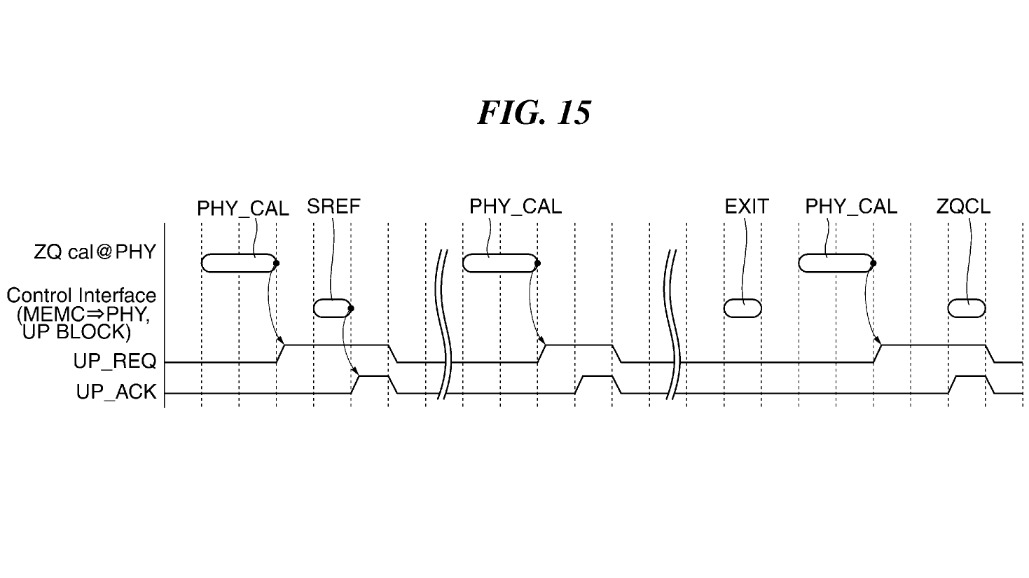

FIG. 15 is a timing chart which is useful in explaining operation of the update process block 125 during self-refresh of the DRAM 123 according to a second embodiment of the present invention.

Referring to FIG. 15, when an UP_REQ signal is asserted by a first PHY_CAL command from the PHY 122, an SREF command which is a self-refresh command is issued by the MEMC 121. When the update process block 125 recognize the SREF command during the assertion of UP_REQ signal, the update process block 125 asserts an UP_ACK signal. In response to this, the DRAM 123 performs self-refresh. Then, the UP_REQ signal is asserted by a second PHY_CAL command from the PHY 122. When the UP_REQ signal is asserted during self-refresh of the DRAM 123, the update process block 125 asserts the UP_ACK signal in the next cycle. As a result, PHY calibration is performed during self-refresh of the DRAM 123. When self-refresh of the DRAM 123 is brought to an end, an EXIT command which is a command to return from self-refresh is issued by the MEMC 121. The subsequent operation is the same as that during normal operation in FIG. 5B.

As described above, when a request to perform PHY calibration is issued during self-refresh of the DRAM, PHY calibration is immediately performed, so that the need to carry out software processing for execution of Update Interface at the time of shifting into self-refresh of the DRAM and at the time of return from self-refresh of the DRAM, that is, PHY calibration control by the CPU is eliminated.

### Other Embodiments

Embodiments of the present invention can also be realized by a computer of a system or apparatus that reads out and executes computer executable instructions recorded on a storage medium (e.g., non-transitory computer-readable storage medium) to perform the functions of one or more of the above-described embodiment(s) of the present invention, and by a method performed by the computer of the system or apparatus by, for example, reading out and executing the computer executable instructions from the storage medium to perform the functions of one or more of the above-described embodiment(s). The computer may comprise one or more of a central processing unit (CPU), micro processing unit (MPU), or other circuitry, and may include a network of separate computers or separate computer processors. The computer executable instructions may be provided to the computer, for example, from a network or the storage medium. The storage medium may include, for example, one or more of a hard disk, a random-access memory (RAM), a read only memory (ROM), a storage of distributed computing systems, an optical disk (such as a compact disc (CD), digital versatile disc (DVD), or Blu-ray Disc (BD)™), a flash memory device, a memory card, and the like.

While the present invention has been described with reference to exemplary embodiments, it is to be understood that the invention is not limited to the disclosed exemplary embodiments. The scope of the following claims is to be accorded the broadest interpretation so as to encompass all such modifications and equivalent structures and functions.

This application claims the benefit of Japanese Patent Application No. 2013-163130 filed Aug. 6, 2013, which is hereby incorporated by reference herein in its entirety.

What is claimed is:

1. A memory interface comprising:
a memory controller configured to control memory;
a physical interface configured to connect the memory and said memory controller to each other and convert data between the memory and said memory controller;
a data conversion unit configured to be disposed between said memory controller and said physical interface, for adjusting output timing of signals output from said memory controller to said physical interface and adjusting output timing of signals output from said physical interface to said memory controller; and
an update process unit configured to be disposed between said memory controller and said physical interface, for controlling executing timing of calibration for adjusting drive performance of said physical interface.

2. The memory interface according to claim 1, wherein said update process unit distinguishes a ZQCS command and a ZQCL command from commands output from said memory controller, and causes said physical interface to perform the calibration in synchronization with the distinguished ZQCS command and ZQCL command.

3. The memory interface according to claim 1, wherein said update process unit recognizes a self-refresh command for the memory output from said memory controller and causes said physical interface to perform the calibration based on the self-refresh command.

4. The memory interface according to claim 1, wherein depending on whether the number of cycles in read latency in accessing the memory is an odd number or an even number, said data conversion unit determines output timing of a read command enable signal for reading read data from the memory.

5. The memory interface according to claim 1, wherein depending on whether a channel based on DFI-I/F standards for accessing the memory is CH0 or CH1, said data conversion unit determines output timing of a read command enable signal for reading read data from the memory.

6. The memory interface according to claim 1, wherein as for read data read from the memory, said data conversion unit determines output timing of a read data signal based on a difference in phase of valid signals when a channel based on DFI-I/F standards is CH0 or CH1.

7. The memory interface according to claim 1, wherein depending on whether the number of cycles in write latency for accessing the memory is an odd number or an even number, said data conversion unit determines output timing of a write data enable signal for writing write data in the memory and output timing of a write data signal.

8. The memory interface according to claim 1, wherein depending on whether a channel based on DFI-I/F standards for accessing the memory is CH0 or CH1, said data conversion unit determines output timing of a write data enable signal and output timing of a write data signal.

9. The memory interface according to claim 3, wherein said update process unit causes said physical interface to immediately perform the calibration when recognizing the self-refresh command.
